(19) United States
(12) Patent Application Publication
(10) Pub. No.: US 2024/0334624 A1
(43) Pub. Date: Oct. 3, 2024

(54) HYBRID SHIELDING AIR VENT PANEL

(71) Applicant: Cisco Technology, Inc., San Jose, CA (US)

(72) Inventors: Jianquan LOU, Shanghai (CN); Alpesh U. BHOBE, Sunnyvale, CA (US)

(21) Appl. No.: 18/193,530

(22) Filed: Mar. 30, 2023

(51) Int. Cl. H05K 5/02; H05K 7/20; H05K 9/00

(52) U.S. Cl. CPC H05K 5/0213; H05K 7/20709; H05K 9/0049; H05K 9/0086

(57) ABSTRACT

The air vent panel and electronic devices described herein provide for a hybrid shielding air vent with a metallic layer which provides structural integrity for the air vent panel and a frequency selective surface (FSS) layer which provides a radiation filter to filter and limit radiation emitting from the electronic device from entering a surrounding environment.

### TECHNICAL FIELD

Embodiments presented in this disclosure generally relate to providing airflow and cooling in and through computer systems such as data center switches and storage systems while also preventing electromagnetic energy from emitting into a surrounding environment. More specifically, embodiments disclosed herein describe an air vent panel which provides for sufficient airflow to enter computing systems without exceeding electromagnetic emission standards.

### BACKGROUND

In large scale computing environments, such as data centers, large numbers of computing systems are grouped together in racks or other assemblies. These computing systems produce large amounts of heat during operation and, in turn, cooling systems provide cooling airflows to and through the components of the computing systems. As computer systems increase in power and complexity, the heat output of these systems also increases.

Additionally, the electronic components of the computing systems also produce electromagnetic radiation or noise. As the power and complexity of the computer systems increase, the related radiation produced by each component in the system increases. While computing systems typically have enclosed chassis which may prevent some portion of the radiation/noise produced by the electronic components from interfering with other closely situation computing systems, certain areas of the chassis, including air vents, may allow for radiation to exit the chassis and potentially interfere with other computing systems in the large scale computing environment.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates an electronic device with a hybrid shielding air vent, according to one embodiment.

FIG. 2 illustrates a cross-section of an electronic device with a hybrid shielding air vent, according to one embodiment.

FIGS. 3A and 3B illustrates cross-sections of a hybrid shielding air vent panel, according to embodiments.

FIGS. 4A and 4B illustrate shielding effectiveness of hybrid shielding air vents, according to embodiments.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One example embodiment includes an air vent panel. The air vent panel includes a metallic structure layer, a frequency selective surface (FSS) layer positioned on a first side of the metallic structure layer, where the FSS layer may include a radiation filter for a first radiation frequency, and a plurality of holes formed through the metallic structure layer and the FSS layer to provide an airflow path from a second side of the metallic structure layer and through the metallic structure layer the FSS layer.

One example embodiment includes an electronic device. The electronic device includes an enclosed chassis with a sidewall. The device also includes an electronic component positioned on a first side of the sidewall and producing radiation in a first radiation frequency. The device also includes a first air vent panel formed in the sidewall, the first air vent panel may include: a metallic structure layer; a frequency selective surface (FSS) layer positioned on a first side of the metallic structure layer, where the FSS layer may include a radiation filter for the first radiation frequency; and a plurality of holes formed through the metallic structure layer and the FSS layer to provide an airflow path from a second side of the metallic structure layer and through the metallic structure layer the FSS layer.

One example embodiment includes a network device. The network device includes an enclosed chassis with a sidewall. The device also includes an electronic component positioned on a first side of the sidewall and producing radiation in a first radiation frequency. The device also includes a first air vent panel formed in the sidewall, the first air vent panel may include: a metallic structure layer; a frequency selective surface (FSS) layer positioned on a first side of the metallic structure layer, where the FSS layer may include a radiation filter for the first radiation frequency; and a plurality of holes formed through the metallic structure layer and the FSS layer to provide an airflow path from a second side of the metallic structure layer and through the metallic structure layer the FSS layer.

### Example Embodiments

Large scale computer systems are an increasingly utilized form of providing networked computing and storage solutions. For example, large scale data centers provide both primary and redundant computing and storage options for a variety of services including governmental, commercial, and consumer computer network based services. A primary concern for data centers and large scale computer systems is providing efficient cooling to these systems. Failing to keep the individual computer systems cool can cause decreased performance and damage to the computer systems. In some examples, data centers are designed to provide cooling airflow to each of the equipment racks and the individual computer systems. The individual computer systems in turn include individual cooling systems, such as fans and air vents, which move cooler ambient air through the computer system to cool the heat producing internal components of the computer system.

Cooling system designers are incentivized to provide as much as possible in an efficient way in order to cool the heat producing components. This may include enlarging openings in the chassis of the computer systems to provide a larger pathway for air to enter and exit the enclosed chassis of the computing system. However, other concerns and design restrictions limit the design of associated air vent panels in the computing systems.

For example, as the processing power of the individual computer systems increases, the amount of electromagnetic energy radiation (noise) produced by the electronic components increases. In some examples, the noise from one computer system may cause electromagnetic interference (EMI) to other computer systems or electronic devices. While EMI may cause limited interference in computer systems which are spaced apart or in individual configurations, in a large scale computing environments, mitigating EMI becomes an essential concern for the various systems in the environment to function.

In some cases, legal regulations and standards define an electromagnetic compatibility (EMC) for electronic devices (including computing systems) which limits an amount of radiation or noise that a given electronic device may produce or emit into the environment. Providing an efficient airflow to heat producing components in a computer system while also meeting EMC regulations and reducing the amount of radiation that emits from the computer systems remains a challenge.

The air vent panel and electronic devices described herein provide for a hybrid shielding air vent with a metallic layer which provides structural integrity for the air vent panel and a frequency selective surface (FSS) layer which provides a radiation filter to filter and limit radiation emitting from the electronic device from entering a surrounding environment.

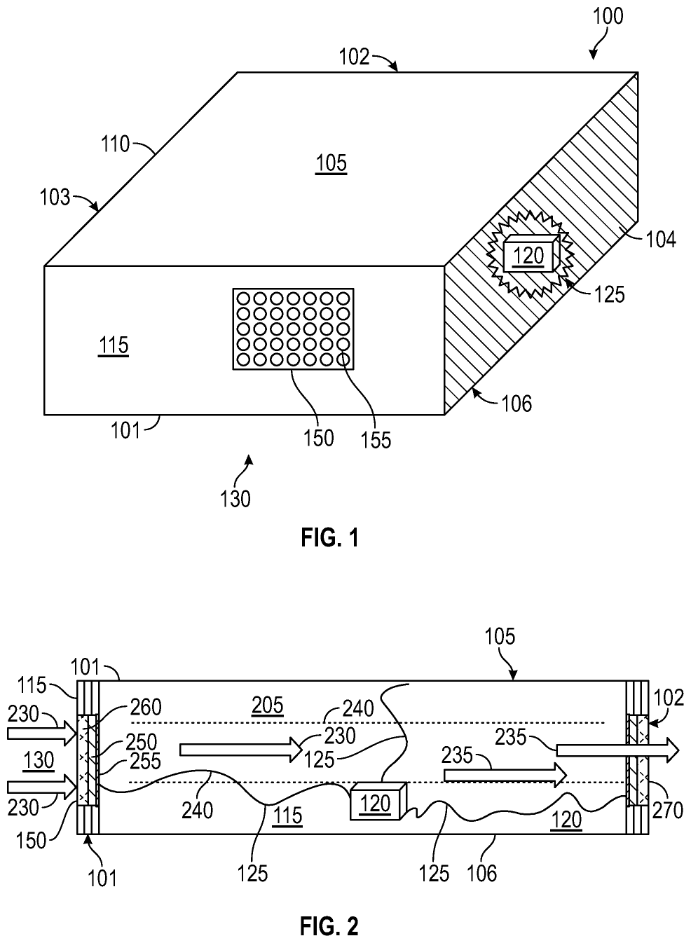

FIG. 1 illustrates an electronic device 100 with a hybrid shielding air vent panel 150, according to one embodiment. The device 100 may be embodied as a network devices, including a network switch, network storage device (server), or other type of electronic device. FIG. 1 is an external perspective view of the device 100. In some examples, the device 100, is installed within a server rack, where cooling air is drawn into the device 100 via the air vent panel 150 and provides a cooling airflow to the components 120, positioned within an interior of the device 100.

In some examples, the device 100 includes an enclosed chassis 110 which provides a housing for electronic and other components of the device 100. The chassis 110 includes a front sidewall 101 and a back sidewall 102. In some examples, the front sidewall 101 includes solid sidewall section 115 and the air vent panel 150. The back sidewall 102 may also include a solid section and air vent panel as shown in more detail in FIG. 2. The enclosed chassis 110 also includes a side 103, a side 104, a top side 105, and a bottom side 106. (The side 104 is shown as semi-transparent in FIG. 1). For ease of illustration the sides 103, 104, 105, and 106 are shown as solid structures. In some examples, these sides may also include air vent panels or other structures formed in or on the sides.

In some examples, the front sidewall 101 is a cool air intake side positioned on a cool air aisle in a large computing environment and the sidewall 102 is an exhaust side facing a warm air aisle in a large scale computing environment. The air vent panel 150 includes a plurality of openings or holes which may include an array of holes 155. The array of holes 155 which provides a pathway for cooling air to flow from an exterior environment 130 to an interior section of the chassis 110. For example, the cooling air flows from outside of the chassis 110 through the air vent panel 150 to heat producing electronic components 120 positioned in the interior section of the chassis 110. While illustrated as a plurality of holes in FIG. 1, the air vent panel 150 may include any type or shape of opening which provides adequate cooling airflow volume through the air vent panel for the device 100.

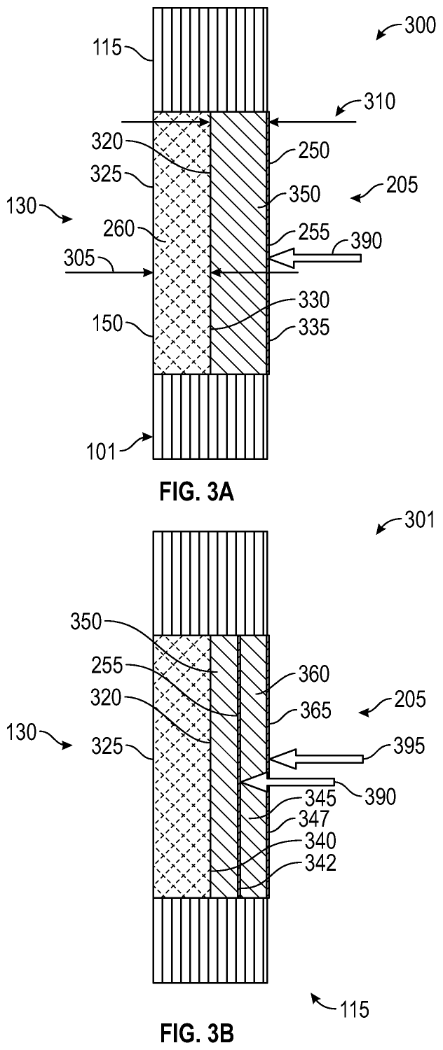

In some examples, the components 120 include ports, optical connections, communication devices (e.g., retimers), application-specific integrated circuits (ASICs), serializer/deserializer (SerDes) channels, and other electronic or communication components. During operation, the components 120 produce heat and electromagnetic radiation. For example, the components 120 emit or produce radiation 125 in the form of electromagnetic energy/noise. For example, the radiation 125 may emit noise at various frequencies including in high range of 25 gigahertz (GHz) to 27 GHz, etc. In order to prevent violations of EMC standards and prevent EMI in other surrounding computing devices, the air vent panel 150 serves as a radiation filter to prevent the radiation 125 from entering the environment 130. The air vent panel 150 is shown in more detail in relation to FIGS. 2 and 3A-B.

FIG. 2 illustrates a cross-section of the device 100 with the air vent panel 150, according to one embodiment. As described in relation to FIG. 1, the device 100 includes components 120 positioned in an interior 205 of the chassis 110. The components 120 produce heat and radiation during operations in the device 100. In some examples, the components 120 are primarily cooled using an ambient cooling airflow. For example, cooling airflow 230 flows through holes 155 (shown in FIG. 1) in the air vent panel 150 into interior 205 of the chassis 110 along an airflow path 240 from the air vent panel 150 to an air vent panel 270. The holes 155 provide space for a volume of airflow sufficient to cool the device 100. In some examples, heat dissipates from the components 120 to the cooling airflow 230 which exits the interior 205 as heated exhaust 235 flowing/exiting via the sidewall 102 and the air vent panel 270. This heat transfer allows for the components 120 to function properly (i.e., not overheat) even as the power and heat generation from the components 120 (and other components in the device 100) increases. In some examples, the air vent panel 150 and the air vent panel 270 are both hybrid shielding air vent panels.

As described in relation to FIG. 1, the components 120 emits radiation 125 which may cause EMI, electromagnetic radiation, or other noise pollution to components outside of the chassis. In some examples, the sides 105 and 106 (as well as (side 103 and side 104 shown in FIG. 1) are formed from solid metal material sheets or other structures and provide a emission barrier, which prevents radiation 125 from emitting from the interior 205 through the respective sides. In some examples, the solid sidewall section 115 of the front sidewall 101 is also a solid metal sheet which provides an emission barrier and prevents radiation 125 from emitting from the interior 205 via the solid sidewall section 115 of the front sidewall 101.

As discussed above, the air vent panel 150 includes the array of holes 155, which may allow some level or portion of radiation 125 to emit from the interior 205 through the holes and into the environment 130. To reduce or prevent an amount of radiation 125 emitting through the holes 155 the air vent panel 150 includes an FSS layer 250 with a FSS material layer 255 and a metallic structure layer 260 as shown in more detail in relation to FIGS. 3A and 3B.

FIGS. 3A and 3B illustrates cross-sections of the hybrid shielding air vent panel 150 with the holes 155 formed through the various layers, according to one embodiment. FIG. 3A illustrates the air vent panel 150 with a single substrate layer in the FSS layer 250. For example, arrangement 300 of the air vent panel 150 includes the metallic structure layer 260 and the FSS layer 250. In some examples, the FSS contains some metal structure and dielectric material to effectively attenuate or reflect electromagnetic noise going through it at a given frequency. The FSS has better shielding performance than pure metallic air vent panel in this certain frequency as described in more detail herein.

In some examples, the layer 260 has a first side 320 and a second side 325, where the second side 325 faces the environment 130. In order to provide structural integrity to the air vent panel 150, the metal structure layer 260 includes a first thickness 305 which is a sufficient thickness (e.g., 1 millimeter (mm)) of metallic material to provide structural integrity for the air vent panel 150.

In some examples, in order to provide shielding or increase the shielding efficiency for the radiation 125, the thickness 305 of the metal structure layer 260 is increased beyond a thickness needed for structural integrity. For example, the thickness 305 is increased to a size of 2 mm or more. In this example, some of the radiation 125 is prevented from passing through the holes 155 and the air vent panel 150, but some frequencies of radiation may still pass through (e.g., the higher frequencies ˜25 GHZ). Additionally, the additional thickness of the metal structure layer 260 increases the weight of the air vent panel 150 and the material cost of fabricating the device 100. In order to avoid the additional weight and complication from the increased thickness 305, the air vent panel includes the FSS layer 250.

The FSS layer includes a first side 330 adjacent or attached to the side 320 of the metal structure layer 260 and a second side 335 facing the interior 205. In some examples, the FSS layer 250 is a radiation filter for a first radiation frequency (e.g., radiation at a first frequency is filtered or blocked by the FSS material layer 255 in the FSS layer 250). In some examples, the FSS layer 250 includes a first substrate section 350 formed from a composite material. For example, the substrate section 350 may be formed from FR-4 or other composite material which serves as a substrate for the FSS material layer 255. The substrate section has a thickness 310 (e.g., 1 millimeter) which provides a structure to form or apply the FSS material layer 255. In some examples, the FSS material layer 255 together with substrate 350 form an LC filter to block EMI.

The composite material weighs less than the metallic material of the metal structure layer 260, which reduces the overall weight of the air vent panel 150. This lower weight provides for efficient radiation blocking without requiring the increased thickness of the substrate section 350 or the air vent panel 150. The composite material of the FSS layer 250 may include a material that does not pass mechanical or structural resistance tests for the chassis 110. For example, the composite material may break or otherwise fracture under a drop test typical for chassis 110 and electronic device 100. The substrate section 350 is thus attached to the metal structure layer 260 for structural support.

In some examples, a first side 330 of the first substrate section 350 is attached to the first side 320 of the metallic structure layer 260. The FSS material layer 255 may include various radiation blocking material or structures to provide radiation blocking/filtering as described herein. The FSS material layer 255 is formed or positioned on a second side 335 of the first substrate section 350 and includes materials to block or otherwise absorb or reflect radiation 125 in a given frequency. For example, radiation 390 includes radiation from the components 120 at a first frequency (˜25 GHZ) and is substantially stopped from passing through the air vent panel 150 at the FSS material layer 255.

In some examples, FSS layer 250 is radiation filter for multiple different frequencies. For example, the FSS material layer 255 filters or block radiation in several frequencies. Additionally, the FSS layer 250 may include several FSS material layers as shown in arrangement 301 in FIG. 3B. In this example, the FSS layer 250 includes two substrates and two FFS material layers.

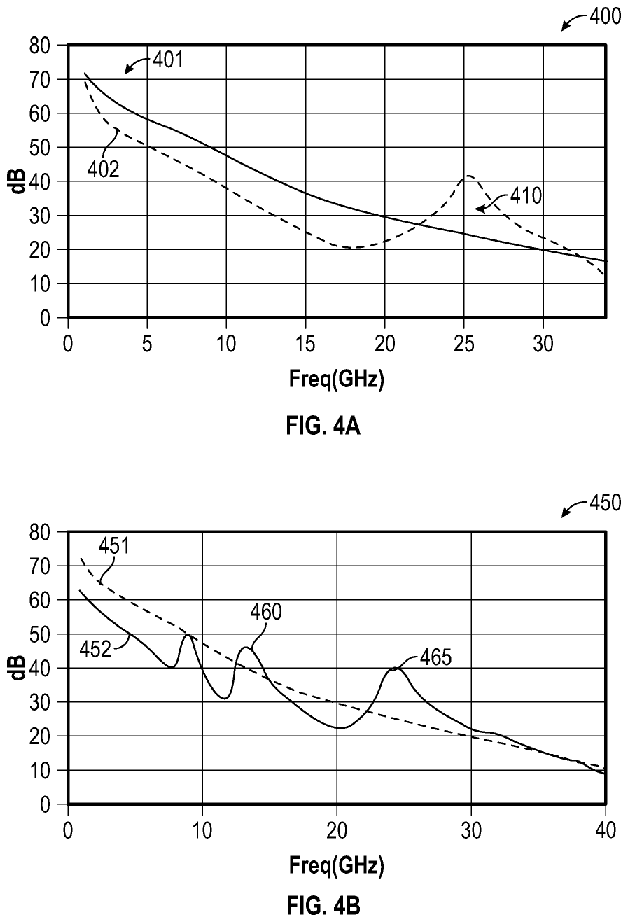

For example, the arrangement 301 of the air vent panel 150 includes the metallic structure layer 260 and the FSS layer 250. The second side 325 of the FSS layer 250 faces the environment 130. The FSS layer 250 includes the first substrate section 350 with the first side 340 adjacent or attached to the side 320 of the metal structure layer 260 and the second side 342 adjacent or attached to a first side 345 of a second substrate section 360. The second substrate 360 has a second side 347 facing the interior 205. In some examples, the FSS material layer 365 is formed or attached to the side 347 of the substrate section 360. The FSS material layer 255 filters or block radiation in a first frequency (e.g., the radiation 390 at ˜25 GHZ) and the FSS material layer 365 filters or blocks radiation 395 in a second frequency (e.g., ˜25.5 GHZ, etc.). While shown as two substrate layers, in FIG. 3B, the FSS layer 250 may also include 3 or more substrate/FSS material to filter out multiple specific frequencies of radiation in the radiation 125 shown in FIG. 1. The improvement in shielding effectiveness with the air vent panel 150 are shown in relation to FIGS. 4A and 4B.

FIGS. 4A and 4B illustrates shielding effectiveness of a hybrid shielding air vent, in accordance with embodiments. The results 400 include a SE plot 401 for a 2 mm thick metallic air vent panel and SE plot 402 for the air vent panel 150 in arrangement 300 shown in FIG. 3A. In this example, at the lower frequencies, such as 5-10 Ghz, the air vent panel 150 and the thick metallic air vent panel provide high levels of shielding (e.g., shielding effectiveness above 40 decibels (dB)). The SE plot 401 and 402 both decrease in effectiveness at the higher frequencies due to the higher frequency radiation's ability to propagate through media/material, including the thick metal air vent and the air vent panel 150 (including the holes 155). In order to increase the shielding effectiveness for the common high frequencies emitted by the components 120 (e.g., frequency 410 at ˜25 Ghz), the FSS material layer 255 is configured to absorbed or reflect radio waves (EMI) in the 25 Ghz frequency which, in turn, increases the shielding effectiveness of the air vent panel 150 back to high levels of shielding for the frequency of concern.

In some examples, there may be multiple frequencies of concern. For example, the components 120 may emit radiation 125 in multiple high frequencies such that additional shielding effectiveness is needed at multiple frequencies. The results 450 include a SE plot 451 for a 2 mm thick metallic air vent panel and SE plot 452 for the air vent panel 150 in arrangement 301 shown in FIG. 3B. In this example, at the lower frequencies, such as 5-10 Ghz, the air vent panel 150 and the thick metallic air vent panel provide high levels of shielding (e.g., above 40 decibels (dB)). The SE plot 451 and 452 both decrease in effectiveness at the higher frequencies due to the higher frequency radiation's ability to propagate through media, including the thick metal and the air vent panel 150 (including the holes 155). In order to increase the shielding effectiveness for the common high frequencies emitted by the components 120 (e.g., frequency 460 at ˜13 GHZ and frequency 465 ˜25 Ghz), the FSS material layer 255 is configured to absorb or reflect radio waves in the 25 Ghz frequency, and the material layer 365 is configured to absorb or reflect waves in the 15 GHz frequency which, in turn, increases the shielding effectiveness of the air vent panel 150 back to high levels of shielding for the frequencies of concern. As shown in both plots 401 and 451, the hybrid shielding air vent panel 150 provides increased shielding effectiveness at frequencies of concern without the increased weight and cost of thick metal layers as described in relation to FIGS. 3A-B.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

In view of the foregoing, the scope of the present disclosure is determined by the claims that follow.

We claim:

1. An air vent panel comprising:
a metallic structure layer;
a frequency selective surface (FSS) layer positioned on a first side of the metallic structure layer, where the FSS layer comprises a radiation filter for a first radiation frequency; and
a plurality of holes formed through the metallic structure layer and the FSS layer to provide an airflow path from a second side of the metallic structure layer and through the metallic structure layer and the FSS layer.

2. The air vent panel of claim 1, wherein the FSS layer comprises;
a first substrate section comprising a composite material, wherein a first side of the first substrate section is attached to the first side of the metallic structure layer; and
a first FSS material layer positioned on a second side of the first substrate section, wherein the first FSS material comprises radiation blocking material for the first radiation frequency.

3. The air vent panel of claim 2, wherein the first FSS layer further comprises a radiation filter for a second radiation frequency, and wherein the FSS layer further comprises:
a second substrate section comprising the composite material, wherein a first side of the second substrate section is positioned on the first FSS material layer; and
a second FSS material layer positioned on a second side of the second substrate section, wherein the second FSS material comprises radiation blocking material for a second radiation frequency.

4. The air vent panel of claim 1, wherein the metallic structure layer comprises a first thickness, wherein the first thickness provides structural integrity for the air vent panel.

5. The air vent panel of claim 1, wherein the plurality of holes comprises an array of holes, wherein airflow along the airflow path comprises a volume of airflow to cool at least one heat producing electronic component.

6. The air vent panel of claim 1, wherein air vent panel is positioned in a sidewall of an enclosed chassis, wherein the FSS layer faces an interior section of the enclosed chassis and the metallic structure layer faces an exterior of the enclosed chassis.

7. The air vent panel of claim 6, wherein the enclosed chassis comprises at least one electronic device positioned in the interior section of the enclosed chassis, wherein the at least one electronic device produces radiation in the first radiation frequency, wherein the air vent panel reduces an amount of radiation that flows from the interior section of the enclosed chassis to the exterior of the enclosed chassis.

8. An electronic device comprising:
an enclosed chassis comprising a sidewall;
an electronic component positioned on a first side of the sidewall and producing radiation in a first radiation frequency;
a first air vent panel formed in the sidewall, the first air vent panel comprising:
a metallic structure layer;
a frequency selective surface (FSS) layer positioned on a first side of the metallic structure layer, where the FSS layer comprises a radiation filter for the first radiation frequency; and
a plurality of holes formed through the metallic structure layer and the FSS layer to provide an airflow path from a second side of the metallic structure layer and through the metallic structure layer the FSS layer.

9. The electronic device of claim 8, wherein the FSS layer comprises;
a first substrate section comprising a composite material, wherein a first side of the first substrate section is attached to the first side of the metallic structure layer; and
a first FSS material layer positioned on a second side of the first substrate section, wherein the second side is opposite the first side of the first substrate section, wherein the first FSS material comprises radiation blocking material for the first radiation frequency, wherein the second side of the first substrate section and the first FSS material layer face the radiation producing component.

10. The electronic device of claim 9, wherein the first FSS layer further comprises a radiation filter for a second radiation frequency, and wherein the FSS layer further comprises:
a second substrate section comprising the composite material, wherein a first side of the second substrate section is positioned on the first FSS material layer; and
a second FSS material layer positioned on a second side of the second substrate section, wherein the second FSS material comprises radiation blocking material for a second radiation frequency.

11. The electronic device of claim 8, wherein the sidewall comprises first sidewall section, wherein the first sidewall section comprises a solid metal material,
wherein the first air vent panel is formed adjacent to the first sidewall section,
wherein the metallic structure layer comprises a first thickness, and
wherein the first thickness provides structural integrity for the first air vent panel.

12. The electronic device of claim 8, wherein the plurality of holes comprises an array of holes, wherein airflow along the airflow path comprises a volume of airflow to cool at least one heat producing electronic component.

13. The electronic device of claim 8, the FSS layer faces an interior section of the enclosed chassis and the electronic component and the metallic structure layer faces an exterior of the enclosed chassis.

14. The electronic device of claim 13, wherein the electronic component is positioned in the interior section of the enclosed chassis, and wherein the first air vent panel reduces an amount of radiation that flows from the interior section of the enclosed chassis to the exterior of the enclosed chassis.

15. The electronic device of claim 14, wherein the enclosed chassis further comprises:
a second sidewall; and
a second air vent panel formed in the second sidewall, wherein the airflow path extends from the first air vent panel through the interior section of the enclosed chassis, and wherein cooling airflow flows through the first air vent panel and heated exhaust flows through the second air vent panel.

16. A network switch comprising:
an enclosed chassis comprising a sidewall;
an electronic component positioned on a first side of the sidewall and producing radiation in a first radiation frequency;
a first air vent panel formed in the sidewall, the first air vent panel comprising:
a metallic structure layer;
a frequency selective surface (FSS) layer positioned on a first side of the metallic structure layer, where the FSS layer comprises a radiation filter for the first radiation frequency; and
a plurality of holes formed through the metallic structure layer and the FSS layer to provide an airflow path from a second side of the metallic structure layer and through the metallic structure layer the FSS layer.

17. The network switch of claim 16, wherein the FSS layer comprises;
a first substrate section comprising a composite material, wherein a first side of the first substrate section is attached to the first side of the metallic structure layer; and
a first FSS material layer positioned on a second side of the first substrate section, wherein the second side is opposite the first side of the first substrate section, wherein the first FSS material comprises radiation blocking material for the first radiation frequency, wherein the second side of the first substrate section and the first FSS material layer face the radiation producing component.

18. The network switch of claim 17, wherein the first FSS layer further comprises a radiation filter for a second radiation frequency, and wherein the FSS layer further comprises:
a second substrate section comprising the composite material, wherein a first side of the second substrate section is positioned on the first FSS material layer; and
a second FSS material layer positioned on a second side of the second substrate section, wherein the second FSS material comprises radiation blocking material for a second radiation frequency.

19. The network switch of claim 16, wherein the electronic component is positioned in an interior section of the enclosed chassis, wherein the first air vent panel reduces an amount of radiation that flows from the interior section of the enclosed chassis to an exterior of the enclosed chassis.

20. The network switch of claim 16, wherein the enclosed chassis further comprises:
a second sidewall; and
a second air vent panel formed in the second sidewall, wherein the airflow path extends from the first air vent panel through an interior section of the enclosed chassis, and wherein cooling airflow flows through the first air vent panel and heated exhaust flows through the second air vent panel.
